(19) United States
(12) Patent Application Publication
(10) Pub. No.: US 2010/0095889 A1
(43) Pub. Date: Apr. 22, 2010

(54) PLASMA DOPING APPARATUS

(76) Inventors: Takayuki Kai, Kyoto (JP); Tomohiro Okumura, Osaka (JP); Hisao Nagai, Osaka (JP)

Correspondence Address: MCDERMOTT WILL & EMERY LLP, 600 13TH STREET, NW, WASHINGTON, DC, 20005-3096, US

(21) Appl. No.: 12/539,949

(22) Filed: Aug. 12, 2009

(30) Foreign Application Priority Data
Aug. 20, 2008 (JP) 2008-211472

(51) Int. Cl. C23C 16/54

(52) U.S. Cl. 118/663

(57) ABSTRACT

There are installed, on a surface of an window on a vacuum chamber side, an insulating side face portion, which extends radially from the center of a generating unit of a plasma generating device and is disposed so as to be orthogonal to a substrate mounting face of an electrode, and a conductive layer, which is made of a material identical to that for the substrate and placed in an area corresponding to the generating unit on the surface of the window on the vacuum chamber side.

### BACKGROUND OF THE INVENTION

The present invention relates to a plasma doping apparatus for introducing an impurity to a surface of a solid-state sample such as a processing substrate (substrate to be processed) used for forming an electronic device, and in particular, relates to a plasma doping apparatus effectively used as an impurity introducing device capable of executing an impurity-introducing method for manufacturing an electronic device.

As a technique for introducing an impurity to a surface of a solid-state sample, there has been known a plasma doping method in which an impurity is ionized and introduced to the solid in a low energy state (for example, see Patent Document 1).

FIG. 15 shows a schematic structure of a plasma processing apparatus used in the plasma doping method as a conventional impurity introducing method described in Patent Document 1. In FIG. 15, a sample electrode 206 on which a sample 209 made of a silicon substrate is mounted is placed in a vacuum container 201. A gas supply device 202 for supplying a doping material gas containing a desired element, for example, B₂H₆, into the vacuum container 201, and a pump 203 for reducing the pressure inside the vacuum container 201 are installed, so that the pressure inside the vacuum container 201 is maintained at a predetermined pressure. A microwave is radiated into the vacuum container 201 by a microwave-guiding tube 219 through a quartz plate 207 serving as a dielectric window. By an interaction between this microwave and a DC magnetic field formed by an electromagnet 214, a magnetic-field-oriented microwave plasma (electron cyclotron resonance plasma) 220 is formed in the vacuum container 201. A high-frequency power supply 210 is connected to the sample electrode 206 through a capacitor 211 so as to control the electric potential of the sample electrode 206. A gas supplied from the gas supply device 202 is supplied into the vacuum container 201 through a gas-supply port 211, and is exhausted into the pump 203 through an exhaust port 212.

In a plasma processing apparatus having this structure, a doping material gas, for example, B₂H₆, which is supplied from the gas-supply port 211, is formed into a plasma by a plasma generating means constituted by the microwave-guiding tube 219 and the electromagnet 214, and as shown in FIG. 17, boron ions in the plasma 220 are introduced to the surface of the sample 209 by the high-frequency power supply 210. Reference symbol 222 represents a sheath.

Since a transistor is not formed only by introducing an impurity by the plasma doping process, an activating process needs to be carried out. The activating process refers to a process in which a layer having an impurity introduced thereto is heated by using a laser annealing method, a flash lamp annealing method, or the like, so as to be formed into an activated state in a crystal. At this time, by effectively heating the very thin layer with the impurity introduced thereto, a shallowly activated layer can be obtained. In order to effectively heat the very thin layer with the impurity introduced thereto, prior to introduction of the impurity, the very thin layer to which the impurity is to be introduced is subjected to a treatment for increasing its absorbing rate with respect to light to be applied thereto from a light source such as a laser or a lamp. This treatment is referred to as a pre-amorphous treatment, and in this treatment, a plasma such as an He gas is generated in the plasma processing apparatus having the same structure as that of the aforementioned plasma processing apparatus, and ions of He and the like generated by the plasma are accelerated toward the substrate by a bias voltage, and made to collide with the substrate so that the crystal structure on the substrate surface is damaged to be formed into an amorphous state.

In accordance with Patent Document 2, in an ion injecting device for injecting an impurity into semiconductor substrate, in order to prevent contaminations from being injected, as well as to make the maintenance easier, a protective member to be attached to the inside of the ion injecting device is prepared, and the inside protective member, which is made of a semiconductor material doped with an impurity, is installed inside the ion injecting device.

Patent Document 1: U.S. Pat. No. 4,912,065

### Patent Document 2: Japanese Unexamined Patent Publication No. 2001-312991

In the plasma doping process, an electromagnetic wave is propagated through the quartz plate 207 serving as a dielectric window so that a plasma is generated. In a case where diborane (B₂H₆) that is a dopant gas containing boron is used, since a bond energy between boron and oxygen is high in silicon and oxygen that are main components of the quartz plate 207, boron is allowed to selectively adhere to the surface of the quartz plate 207 as shown in FIG. 17, so that it protects the quartz plate 207 from impact of ions in the plasma; thus, even when ions in the plasma collide therewith, oxygen in the quartz is hardly decomposed, greatly reducing the possibility of oxygen discharge into the plasma. For this reason, oxygen ions ionized in the plasma are hardly injected to the processing substrate 9.

However, in a case where arsine or phosphine serving as a dopant gas containing arsenic or phosphorous is used, since the bond energy with oxygen becomes lower in silicon and oxygen that are the main components of the quartz plate 207, arsenic or phosphorous exerts only a weak adhesive strength to the surface of the quartz plate 207, as shown in FIG. 18, due to impact of ions in the plasma, oxygen is discharged into the plasma (FIG. 16), with a result that the oxygen partial pressure increases in the plasma so that the oxygen containing impurity is injected to the surface of the sample 209 made of a silicon substrate. FIG. 6 shows an arsenic concentration as well as silicon and oxygen concentrations. As indicated in FIG. 6, oxygen is allowed to present even to a depth of about 6 nm from the surface, that greatly exceeds an approximate film thickness of a natural oxidized film, with no peak of silicon being observed to the depth of this extent. Moreover, a peak of arsenic is also present in the same depth, thereby clearly indicating that much oxygen exists on the silicon surface.

Therefore, in order to solve the above-mentioned issues, it is an object of the present invention to provide a plasma doping apparatus that can reduce a layer having a high concentration of oxygen on a surface of a substrate to be processed such as a silicon substrate as an example to a film thickness as thin as a natural oxidized film so as to carry out a doping process on the surface of the substrate with a desirable impurity distribution.

### SUMMARY OF THE INVENTION

In order to achieve the above-mentioned object, the present invention has the following arrangements.

According to a first aspect of the present invention, there is provided a plasma doping apparatus characterized by comprising:

a vacuum container forming a vacuum chamber;

an electrode, disposed inside the vacuum chamber, on a substrate mounting face of which a substrate to be processed is mounted;

a supply device for supplying a dopant gas into the vacuum container;

a pressure controlling device for maintaining an inside of the vacuum container at a constant pressure;

a plasma generating device for generating a plasma;

a high-frequency power supply device for applying a high-frequency power to the electrode with the substrate mounted thereon, so that the dopant is injected to a surface of the substrate; and

an insulating window for allowing an electromagnetic wave to passed therethrough, so as to generate the plasma by the plasma generating device, wherein

an insulating side face portion is installed, which extends radially from a center of a generating unit of the plasma generating device, and is disposed on a surface of the window on the vacuum chamber side so as to be orthogonal to the substrate mounting face of the electrode, and

a conductive layer made of a material identical to that for the substrate is provided in an area corresponding to the generating unit of the plasma generating device on the surface of the window on the vacuum chamber side.

According to a second aspect of the present invention, there is provided the plasma doping apparatus according to the first aspect, characterized in that the insulating side face portion of the window is constituted by side faces along radial directions of beams that radially extend from a center portion of the window, each of the beams having a height of 10 mm or more, with the side faces of the beams each being made of an insulating substance.

According to a third aspect of the present invention, there is provided the plasma doping apparatus according to the first or second aspect, characterized in that the dopant gas, which contains arsenic or phosphorous atoms, is an element selected from the group consisting of arsine, phosphine, arsenic trifluoride, arsenic pentafluoride, arsenic trichloride, arsenic pentachloride, phosphorous trichloride, phosphorous pentachloride, phosphorous trifluoride, phosphorous pentafluoride, and phosphorous oxychloride.

According to a fourth aspect of the present invention, there is provided the plasma doping apparatus according to the first aspect, characterized in that the insulating side face portion of the window is constituted by a side face along a radial direction of a single beam that radially extends from a center portion of the window.

According to a fifth aspect of the present invention, there is provided the plasma doping apparatus according to any one of the first to fourth aspects, characterized in that the window is made of an insulating substance having a resistivity of 10 kΩcm or more.

According to a sixth aspect of the present invention, there is provided the plasma doping apparatus according to any one of the first to fifth aspects, characterized in that the conductive layer of the window has a resistivity of 1 kΩcm or less.

According to a seventh aspect of the present invention, there is provided the plasma doping apparatus according to the first aspect, characterized in that the insulating side face portion of the window is constituted by side faces along radial directions of beams that radially extend from a center portion of the window, each of the beams being disposed in an area inside a peripheral frame portion of the window to be tightly made in contact with and secured to the vacuum container.

According to an eighth aspect of the present invention, there is provided the plasma doping apparatus according to any one of the first to seventh aspects, characterized in that an induction coupling plasma source, a helicon-wave plasma source, a magnetic neutral loop plasma source, or a magnetic-field-oriented microwave plasma source is used as a means for generating the plasma.

According to a ninth aspect of the present invention, there is provided the plasma doping apparatus according to the eighth aspect, characterized in that the insulating side face portion of the window is constituted by side faces along radial directions of beams that radially extend from a center portion of the window, with outer edges of the beams in the radial directions of the window for allowing an electromagnetic wave to be transmitted therethrough being positioned outside an outer edge of the generating unit of the plasma generating device while extending from a center of the window.

According to a 10th aspect of the present invention, there is provided the plasma doping apparatus according to the first aspect, characterized in that the insulating side face portion of the window is constituted by a side face along a radial direction of a concave portion that is placed on the surface of the window on the vacuum chamber side.

According to an 11th aspect of the present invention, there is provided the plasma doping apparatus according to the first aspect, characterized in that the insulating side face portion of the window is constituted by a side face along a radial direction of a step portion that radially extends from a center portion of the window.

Since the conductive layer made of the same material as that for the substrate is provided in the area corresponding to the generating unit of the plasma generating device on the surface of the window on the vacuum chamber side, the adhesive strength of the material (for example, a dielectric substance) for the window to the conductive layer that is made of the same material as that for the substrate is stronger than adhesive strength to conventional arsenic or phosphorous, so that the conductive layer can prevent oxygen from being discharged into a plasma due to impact of ions in a plasma, consequently to suppress an increase in the oxygen partial pressure in the plasma. Moreover, since an eddy current to be generated on the surface of the conductive layer upon application of an AC magnetic field generated by the generating unit of the plasma generating device can be suppressed by the insulating side face portion of the window, it becomes possible to prevent the AC magnetic field from being attenuated by a resistance loss due to the generation of the eddy current so as to cause a reduction in the plasma density.

With this arrangement, in comparison with the conventional structure, the layer with a high oxygen concentration on the surface of a sample (for example, a silicon substrate) is reduced to a film thickness as thin as the natural oxidized film, so that a doping process is carried out on the surface of the sample (for example, a semiconductor circuit device of a silicon substrate), with a desirable impurity distribution. For example, upon manufacturing an n-type semiconductor by using a dopant gas containing arsenic or phosphorous, the film thickness of the layer with a high oxygen concentration on the surface of the semiconductor substrate can be reduced to the level of the natural oxidized film of an untreated silicon substrate.

### BRIEF DESCRIPTION OF THE DRAWINGS

These and other aspects and features of the present invention will become clear from the following description taken in conjunction with the preferred embodiments thereof with reference to the accompanying drawings, in which:

FIG. 1 is a structural view that shows a plasma doping apparatus in accordance with a first embodiment of the present invention;

FIG. 2(A) is a bottom view of a window of an upper quartz plate of the plasma doping apparatus of the embodiment of the present invention, and FIG. 2(B) is a B-B line cross-sectional view of the window in FIG. 2(A) of the plasma doping apparatus;

FIG. 3 is a view that shows a state of ions and atoms inside a plasma as well as on the quartz plate during a plasma doping process in which arsine is used in the embodiment of the present invention;

FIG. 4 is an explanatory view that shows a state of a processing substrate surface during the plasma doping process of the embodiment of the present invention;

FIG. 5 is a graph that shows relationships among a concentration of arsenic, the counted numbers of elements of silicon and oxygen (SiO concentration (arbitrary unit)) and the depth of the substrate, immediately after the plasma doping process in accordance with the first embodiment of the present invention;

FIG. 6 is a graph that shows a concentration of arsenic and the counted numbers of elements of silicon and oxygen, immediately after a plasma doping process in accordance with a conventional example;

FIG. 7 is a graph that shows relationships among a concentration of arsenic in a p-type silicon substrate, the counted numbers of elements of silicon and oxygen (SiO concentration (arbitrary unit)), and the depth of the substrate, in the plasma doping process of the first embodiment of the present invention;

FIG. 8(A) is a bottom view of a window of an upper quartz plate of a plasma doping apparatus in accordance with a second embodiment of the present invention, and FIG. 8(B) is a B-B line cross-sectional view of the window in FIG. 8(A) of the plasma doping apparatus;

FIG. 9 is a window silicon-pattern view of an upper quartz plate of a plasma doping apparatus in accordance with a modified example of the second embodiment of the present invention;

FIG. 10 is a perspective view showing a window of an upper quartz plate of a plasma doping apparatus in accordance with another embodiment of the present invention;

FIG. 11 is a perspective view showing a window of an upper quartz plate of a plasma doping apparatus in accordance with still another embodiment of the present invention;

FIG. 12(A) is a bottom view of the window of the upper quartz plate of the plasma doping device in accordance with still another embodiment of the present invention, and FIG. 12(B) is a B-B line cross-sectional view of the window of FIG. 12(A) of the plasma doping apparatus;

FIG. 13 is a perspective view of the window of the upper quartz plate of the plasma doping device in accordance with still the other embodiment of the present invention of FIG. 12;

FIG. 14 is a perspective view showing a window of an upper quartz plate of a plasma doping apparatus in accordance with still another embodiment of the present invention;

FIG. 15 is a block diagram that shows a plasma doping processing device in accordance with the conventional embodiment;

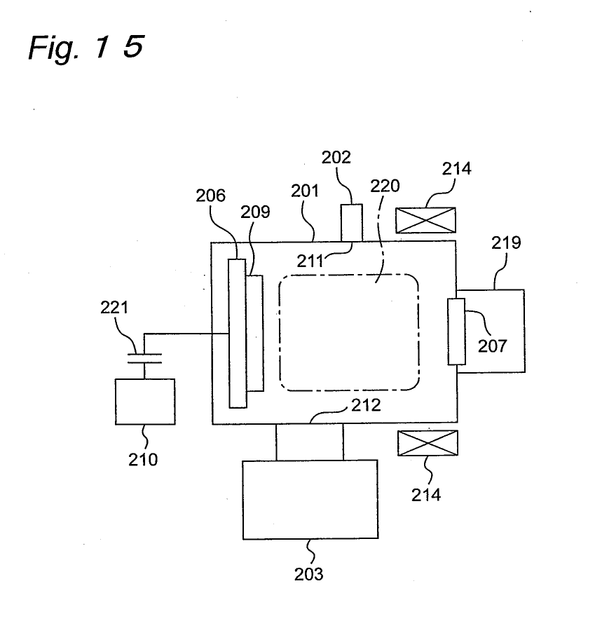

FIG. 16 is an explanatory view that shows a state of a processing substrate surface during the plasma doping process of the conventional embodiment;

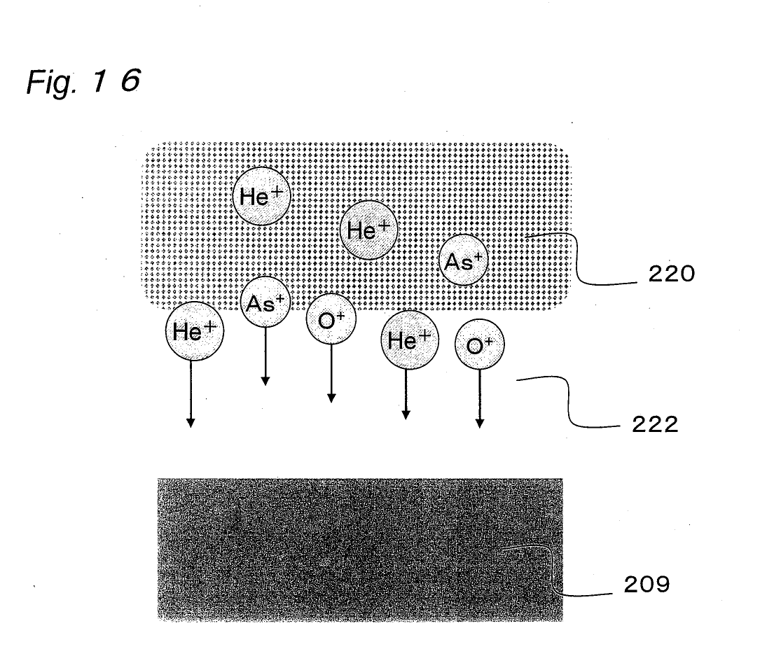

FIG. 17 is a view that shows a state of ions and atoms inside a plasma as well as on a quartz plate during a plasma doping process in which diborane is used in the conventional embodiment;

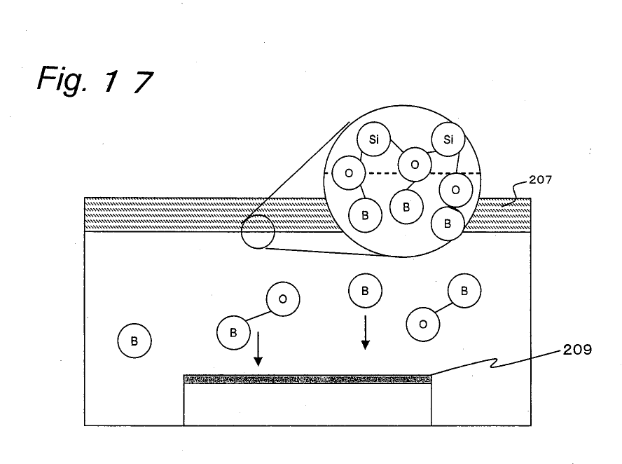

FIG. 18 is a view that shows a state of ions and atoms inside a plasma as well as on a quartz plate during a plasma doping process in which arsine is used in the conventional embodiment; and

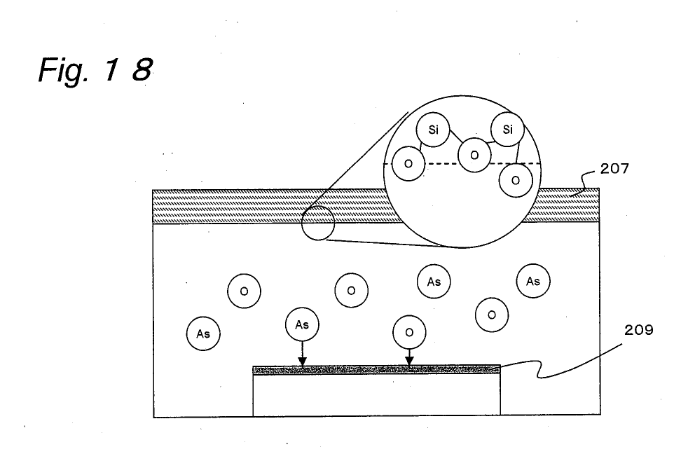

FIG. 19 is a perspective view for explaining an electric current (eddy current) in a rotation direction around the center of a dielectric window.

### DETAILED DESCRIPTION OF THE PREFERRED EMBODIMENTS

Prior to continuation of description of the present invention, the same components in the accompanying drawings are indicated by the same reference symbols.

Referring to the drawings, the following description will discuss embodiments of the present invention in detail.

### First Embodiment

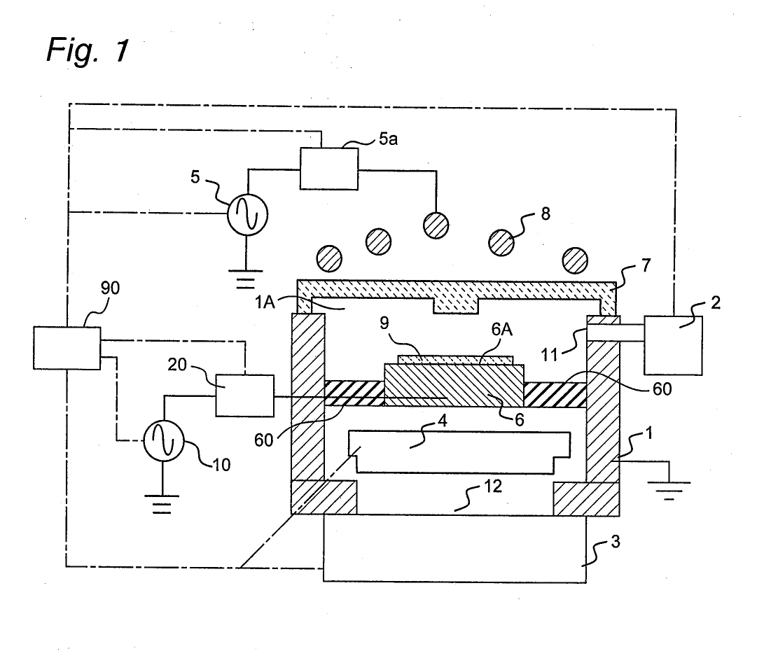

Referring to FIGS. 1 to 7, the following description will discuss a plasma doping apparatus in accordance with a first embodiment of the present invention.

FIG. 1 shows a cross-sectional view of a plasma doping apparatus in accordance with the first embodiment of the present invention. In FIG. 1, a predetermined gas is supplied into a vacuum container 1 having, for example, a cylindrical shape, which has a vacuum chamber 1A formed therein, and is earthed, from a gas supply device 2 serving as one example of a dopant gas supplying device, through a gas supply port 11 on a side wall of the vacuum container 1, while an exhausting process inside the vacuum container 1 is carried through an exhaust port 12 on the bottom face of the vacuum container 1 by using a turbo molecular pump 3 serving as one example of an exhausting device, so that the pressure inside the vacuum container 1 is kept at a predetermined pressure by a pressure-adjusting valve 4 for opening and closing the exhaust port 12. The turbo molecular pump 3, the pressure-adjusting valve 4, and a pressure control unit of a control device 90 constitute one example of a pressure control device. By using a high-frequency power supply 5 serving as one example of a plasma-generating high-frequency power supply device, for example, high-frequency power of 13.56 MHz is supplied to a coil 8 formed near the upper face on the outside of a round dielectric window 7 that is formed on an upper round opening of the vacuum container 1 in a manner so as to face a processing substrate mounting face 6a of a sample electrode 6, through a matching device 5a so that an induction-coupling-type plasma can be generated in a space above the sample electrode 6 and periphery of the space of the vacuum container 1 inside the vacuum container 1. These plasma-generating high-frequency power supply 5, matching device 5a, and coil 8 constitute a plasma generating device or means. A silicon substrate 9 as one example of a sample is mounted on the processing substrate mounting face 6a of the sample electrode 6 that is placed inside the vacuum container 1 with insulators 60 serving as a plurality of supporting pillars interposed therebetween.

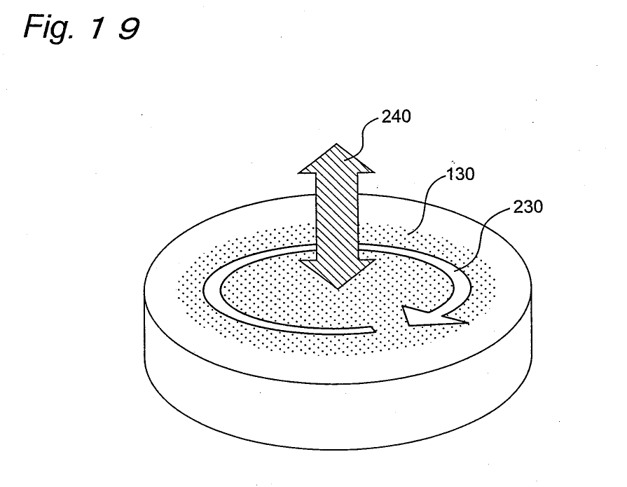

In the first embodiment, the structure of the inner face on the vacuum chamber 1A side of the round dielectric window 7 is designed in the following manner. On a surface (inner face) 7a of the window 7 on the vacuum chamber side, made of an insulating material, for example, a dielectric substance, that allows an electromagnetic wave to pass therethrough so as to generate the plasma in the plasma generating device, a dielectric side face portion 40 that is composed of a dielectric substance and disposed so as to be extended radially from a base point, with the base point being allowed to face the center of the coil 8 serving as one example of a generating unit of the plasma generating device, and also to be orthogonal to the processing substrate mounting face 6a of the electrode 6, is formed, and on the surface 7a, a conductive layer 13 containing the same material as that for the sample 9 (including a substance mainly composed of the same material as that for the sample 9) is formed on the surface 7a so that an eddy current is prevented from being generated by a dielectric side face portion 40, while the density of the plasma being maintained as it is. That is, as shown in FIG. 19, in a case where an AC magnetic field 240, generated by the coil 8, is applied to a conductive substance 130 (for example, a silicon conductive layer 13) on the dielectric window 7, since an eddy current 230 is generated on the surface of the conductive substance 130, the AC magnetic field 240 is attenuated by a resistance loss caused by the generated eddy current 230, with a result that the plasma density is lowered. In order to prevent this phenomenon, the insulating layer 40 is disposed along a radial direction in the conductive substance 130 so that one portion of the conductive substance 130 is lacked; thus, the generation of the eddy current 230 can be effectively suppressed.

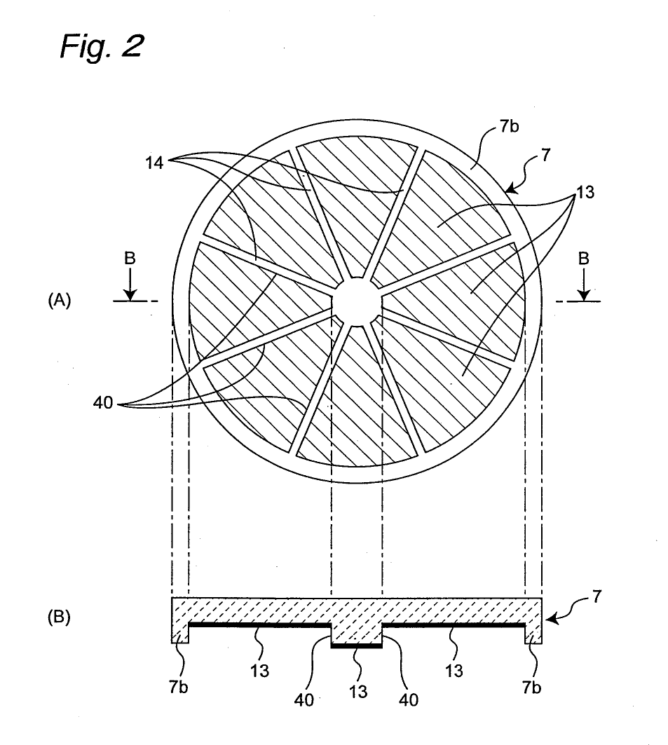

More specifically, as shown in FIGS. 2(A) and 2(B), at least one of beams 14 (for example, eight in FIGS. 2(A) and 2(B)) that extend radially from the center of the round dielectric window 7 is installed (in a case of a plurality of beams 14, the beams 14 are disposed with predetermined gaps (for example, with equal gaps or desired gaps)), and a substance, mainly composed of the same material as that for the substrate 9, is preliminarily deposited on each of inner faces 7a (regions indicated by slanting lines in FIG. 2(A)) of the dielectric window 7 that face the surface of the substrate 9 so as to form a conductive layer 13, while the substance mainly composed of the same material as that for the substrate 9 is not allowed to be deposited on the two side faces (at least one of the side faces) of the beam 14 so that the same material as that for the dielectric window 7 of the dielectric window 7 is exposed to each of the side faces; thus, a dielectric side face portion 40 serving as an insulating layer is formed. In this case, for example, since the substrate 9 is a silicon substrate, the substance to be deposited on the dielectric window 7 is prepared as silicon so that the conductive layer 13 is made of silicon. For example, since the material for the dielectric window 7 is quartz, the dielectric side face portion 40 is made of quartz. In a case where the dielectric side face portion 40 is made of quartz, since quartz that is a material having the least content of contaminants is utilized, it is possible to exert a metal contamination reducing effect in the semiconductor manufacturing process. In this case, since a bond energy between silicon that is the same material as that for the substrate 9 and quartz is stronger than the bond energy between arsenic or phosphorous and quartz, the adhesive strength between silicon and quartz in accordance with the present embodiment is stronger than the conventional adhesive strength between arsenic or phosphorous and a quartz plate.

Moreover, the thickness of the conductive layer 13 needs to be set to at least 1 μm so as to prevent oxygen from being released into a plasma due to impact of ions in the plasma, and is preferably set to about 100 μm. When the thickness of the conductive layer 13 is substantially set to 100 μm, it is possible to sufficiently achieve the above-mentioned effects.

Additionally, in FIGS. 2(A) and 2(B), the eight beams 14 are respectively connected to one after another at their end portions on the center side, and the respective end portions on the peripheral edges are coupled to the peripheral frame portion 7b of the inner face 7a of the window 7 to form an integral unit. The peripheral frame portion 7b is a portion that is made in contact with the upper end face of the vacuum container 1 to be secured thereon, with the gap between the upper end face of the vacuum container 1 and the peripheral frame portion 7b being tightly sealed, so as to maintain the vacuum state, and in order to ensure its sealing property, it is preferable not to form the dielectric side face portion 40 and each of the beams 14 on the peripheral frame portion 7b. In other words, each of the beams 14 is preferably disposed in an area inside the peripheral frame portion 7b of the window 7 that is tightly made in contact with and secured onto the upper end face of the vacuum container 1.

As shown in FIG. 19, the height (dimension of the window 7 in the thickness direction) of each beam 14 is preferably set to 10 mm or more so as to block off an electric current (eddy current) 230 in the rotation direction around the center of the dielectric window 7. The reason for this is because the height of the beam 14, that is, the width of the dielectric side face portion 40 (dimension of the window 7 in the thickness direction), of less than 10 mm fails to provide a sufficient effect to block off an eddy current. For example, the height of the peripheral frame portion 7b is set to 35 mm.

In this case, the position of the outer edge of the beam 14 in the radial direction of the dielectric window 7 through which an electromagnetic wave is transmitted needs to be positioned so as to extend from the center of the window 7 to the outer side from the outer edge (radius of the outermost circumference) of the coil 8 that serves as one example of a plasma generation apparatus. The reason for this is because, since an eddy current 230 is generated on the silicon 13 centered on the coil 8 center by the coil 8 to cause a loss due to the electric current exchanged into heat to attenuate the plasma, the outer edge in the radial direction of each beam is positioned in a manner so as to extend from the center of the window 7 to the outer side farther from the outer edge (radius of the outermost circumference) of the coil 8 so that the eddy current 230 caused by the coil 8 can be effectively blocked off or suppressed. As a result, the area of the frame portion outside each beam 14 (portion to which quartz is exposed, that is, the peripheral frame portion 7b) can be made smaller, and the area that is exposed to impact of ions in the plasma can be made smaller.

Moreover, as a modified example of the first embodiment, instead of forming the beams 14 sticking out from the inner face 7a downward, concave groove portions are formed on the inner face 7a of the window 7 at portions corresponding to the beams 14 in a manner so as to reverse the concave/convex relationship on the cross section of FIG. 2(B) so that the groove wall faces of each concave groove portion may be formed as the dielectric side face portions 40.

Moreover, the sample electrode 6 is placed outside the vacuum container 1 so as to be connected to a high-frequency power applying high-frequency power supply serving as one example of a high-frequency power applying device for supplying high-frequency power, and the high-frequency power supply 10 is driven and controlled by the control device 90 so that the electric potential of the sample electrode 6 is controlled so as to allow a silicon substrate 9 serving as one example of a sample to be mounted on the sample electrode 6 to have a negative electric potential to the plasma. The control device 90 controls respective operations of the gas supply device 2, the turbo molecular pump 3, the pressure adjusting valve 4, the high-frequency power supply 5, the matching device 5a, the high-frequency power supply 10, and the matching device 20 so that a plasma doping method can be executed.

After the silicon substrate 9 has been mounted on the processing substrate mounting face 6a of the sample electrode 6, while the vacuum container 1 is being evacuated through the exhaust port 12, with the temperature of the sample electrode 6 being maintained at, for example, 10° C. by a temperature-adjusting device (not shown) installed in the sample electrode 6, for example, 50 sccm of a helium gas is supplied into the vacuum container 1 from the gas supply device 2 through the gas supply port 11, and 3 sccm of an arsine (AsH₃) gas serving as one example of a doping material gas (dopant gas) is also supplied thereto so that the pressure of the vacuum container 1 is maintained at, for example, 3 Pa by open/close controlling the pressure adjusting valve 4 by the control device 90.

In this case, the dielectric window 7 is made of, for example, quartz, and the quartz is an insulating substance having a resistivity of 10 kΩcm or more, for example, about 100 GΩ cm. Moreover, for example, the substance of which the substrate 9 is mainly composed is silicon, and since silicon has a varying resistivity by doping, the resistivity of silicon is 1 kΩcm or more, while the resistivity of non-doped silicon is 1 kΩcm or less, which is unchanged. That is, when doped, the resistivity of silicon becomes smaller. In other words, since the resistivity becomes smaller in comparison with a resistivity of the non-doped silicon, the resistivity of the conductive layer 13 of the dielectric window 7 is preferably set to 1 kΩcm or less. The silicon to be used for forming the conductive layer 13 of the dielectric window 7 is not necessarily required to have a single-crystal structure.

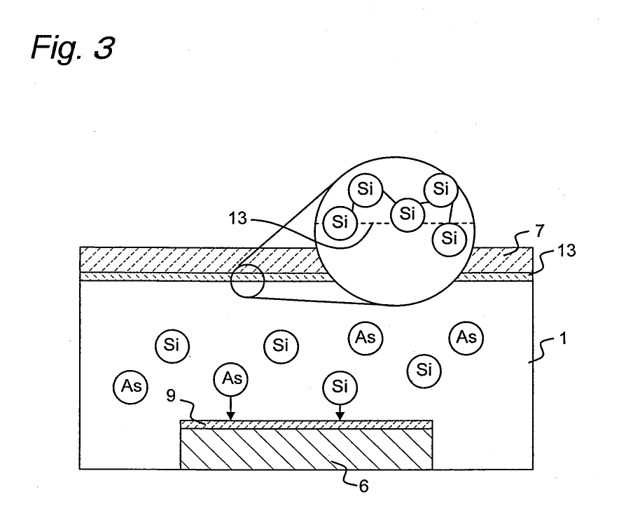

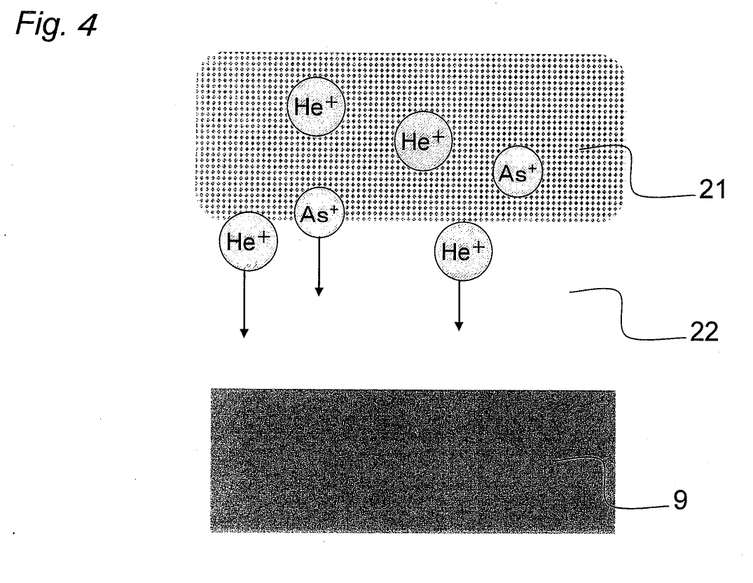

FIG. 3 is a view that shows a state of an inner face 7a on the vacuum side of the dielectric window 7 in the plasma doping process executed in the first embodiment of the present invention. FIG. 4 is an explanatory view that shows a state on the processing substrate surface during the plasma doping process in accordance with the first embodiment of the present invention. Reference symbol 21 represents a plasma, and 22 represents a sheath. In the device of FIG. 1, since the final terminal end of the inner face 7a of the dielectric window 7 is made of silicon of the conductive layer 13, the conductive layer 13 can suppress oxygen from being discharged into the vacuum chamber 1A from the dielectric window 7, as shown in FIGS. 3 and 4, and no oxygen is subsequently injected from the plasma 21 to the sample substrate 9 so that the oxygen concentration on the surface of the silicon substrate 9 can be reduced.

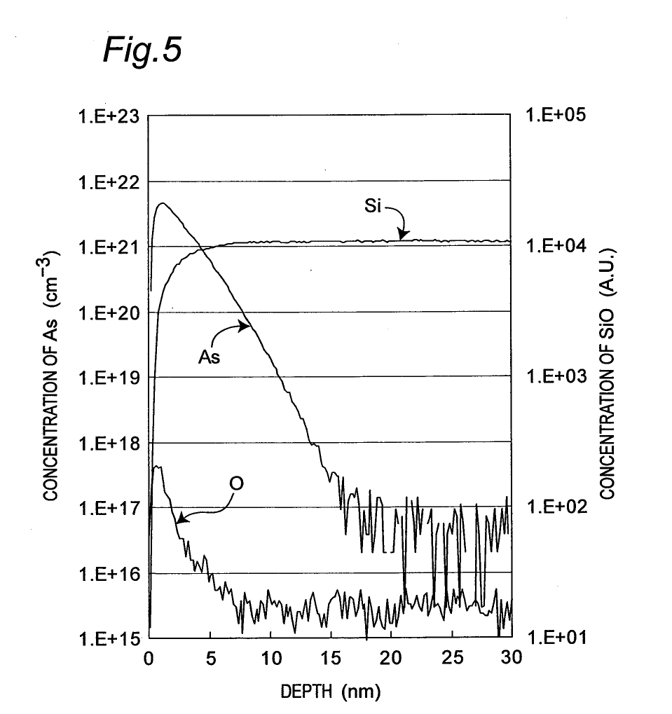

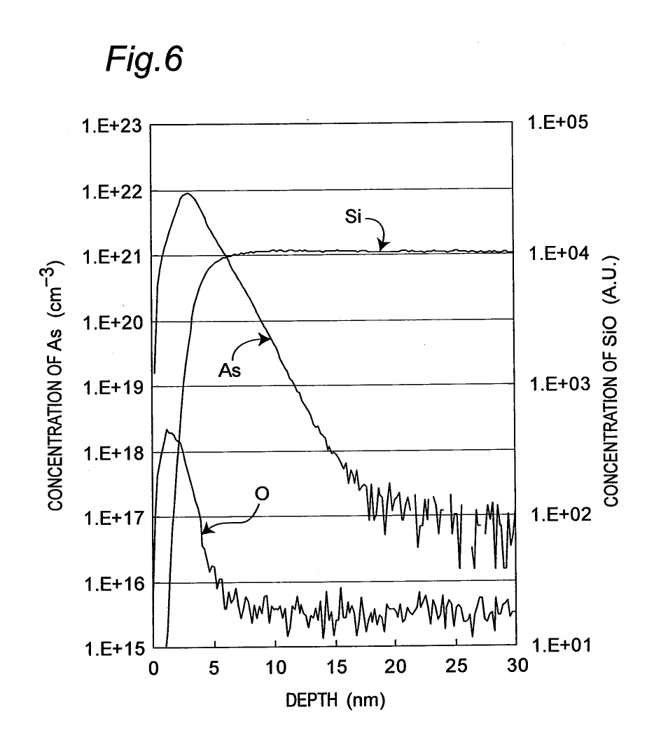

FIGS. 2(A) and 2(B) show the arsenic concentration and silicon and oxygen concentrations near the surface of the processing substrate 9 that has been subjected to a plasma doping process by using an arsine gas. In this case, the silicon and oxygen concentrations, which are indicated by arbitrary units, can be represented by the counted numbers of silicon atoms and oxygen atoms, for example, in SIMS (Secondary Ionization Mass Spectrometer) measurements. This is because the counted number (counts/s) is in proportion to the concentrations of silicon and oxygen. FIG. 5 is a graph that shows the arsenic concentration and the counted numbers of elements of silicon and oxygen, immediately after the plasma doping process by the first embodiment of the present invention. In comparison with FIG. 6 of a conventional example and FIG. 5 of the first embodiment, the oxygen concentration and the depth thereof are different from each other; thus, upon carrying out the plasma doping process in accordance with the first embodiment of the present invention, the injection depth of oxygen is about 3 nm and the peak of arsenic is about 2 nm, which only form a level of a natural oxidized film. In contrast, as described earlier, in FIG. 6, the injection depth of oxygen reaches as far as about 6 nm, and no peak of silicon appears up to the depth of this level. Moreover, the peak of arsenic is present in the depth of the same level so that much oxygen is located on the silicon surface.

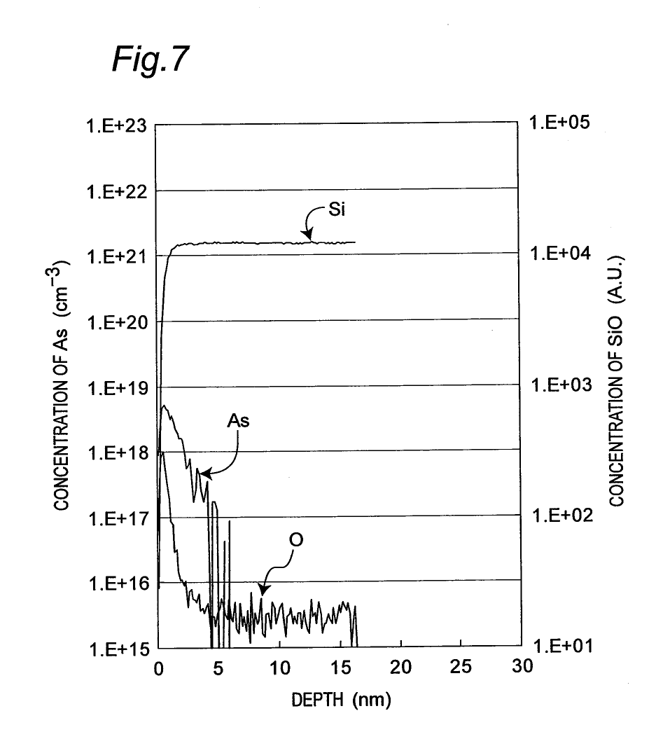

FIG. 7, which shows results of SIMS measurements of a p-type silicon substrate, indicates the arsenic concentration and the counted numbers of silicon atoms and oxygen atoms. FIG. 7 shows that the film thickness of a natural oxidized film is about 2 nm, and that the plasma doping processing method in the first embodiment of the present invention forms a film thickness in the same level.

For example, an arsine gas has been proposed as one example of the doping material gas used for a silicon semiconductor; however, another gas, such as phosphine, arsenic trifluoride, arsenic pentafluoride, arsenic trichloride, arsenic pentachloride, phosphorous trichloride, phosphorous pentachloride, phosphorous trifluoride, phosphorous pentafluoride, or phosphorous oxychloride, serving as a doping material gas for an n-type semiconductor, may be used.

As an actual example, in gas supply and exhaust processes in the first step S1, the pressure in the vacuum container 1 is set to 3 Pa, the He flow rate is set to 50 sccm, the AsH₃ flow rate is set to 3 sccm, (V·p/Q) is 6.7 s, and the exhaust process is turned on, while high frequency powers (ICP/BIAS) of the plasma generating high-frequency power supply 5 and the high-frequency power applying high-frequency power supply 10 are set to 0/0 (W).

Next, in the gas supply and exhaust processes in the second step S2, the pressure in the vacuum container 1 is set to 3 Pa, the He flow rate is set to 50 sccm, the AsH₃ flow rate is set to 3 sccm, (V·p/Q) is 6.7 s, and the exhaust process is turned on, while high frequency powers (ICP/BIAS) of the plasma generating high-frequency power supply 5 and the high-frequency power applying high-frequency power supply 10 are set to 800/200 (W). In this case, suppose that the volume of the vacuum chamber 1A of the vacuum container 1 is V (L: litters), the pressure inside the vacuum container 1 is p (Torr), and the flow rate of the gas to be supplied is Q (Torr·L/s). In these processes, a plasma discharge is started, and a plasma doping process for injecting arsenic to the surface of a sample 9 made of a silicon substrate is carried out.

Next, in step S3, under control of the control device 90, the plasma generating high-frequency power supply 5 and the high-frequency power applying high-frequency power supply 10 are turned off to complete the plasma discharge, thereby completing the plasma doping process.

In accordance with the first embodiment, by carrying out the plasma doping process using the dielectric window 7 having the beams 14 as described earlier, that is, the window 7 having the conductive layer 13 and the dielectric side face portion 40, the plasma doping process can be executed while effectively suppressing the generation of an eddy current 230 by the dielectric side face portion 40, with the density of plasma being maintained as it is. Consequently, the layer with a high oxygen concentration on the surface of the sample 9 made of the silicon substrate is reduced to a film thickness as thin as the natural oxidized film so that a doping process is carried out on the surface of a silicon substrate (for example, a semiconductor circuit device), with a desirable impurity distribution. For example, upon manufacturing an n-type semiconductor by using a dopant gas containing arsenic or phosphorous, the film thickness of the layer with a high oxygen concentration on the surface of the semiconductor substrate can be reduced to the level of the natural oxidized film of an untreated silicon substrate, as shown in FIG. 7.

### Second Embodiment

Referring to FIGS. 1, and 3 to 9, the following description will discuss a second embodiment of the present invention. In the present invention, as the structure having the conductive layer 13 and the dielectric side face portion 40, not limited to the structure having eight beams like the first embodiment, another structure may be used, and as one example of this, the second embodiment is proposed.

FIG. 1 is a cross-sectional view showing a plasma doping apparatus to be used in the second embodiment of the present invention; however, since the plasma generating method has been explained in the first embodiment, the description thereof will not be repeated. The following description of the second embodiment will mainly discuss points that are different from the first embodiment.

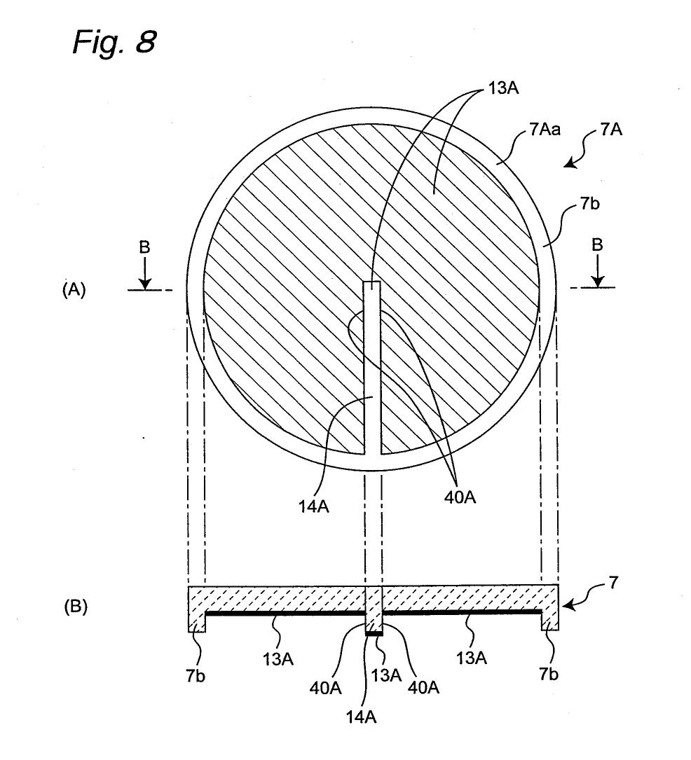

In a case where, as described in the first embodiment also, the conductive layer 13 is formed by allowing silicon 13 to adhere to the front face (inner face) 7a of the dielectric window 7 without using the beam structure, since single-crystal or amorphous silicon has a certain degree of conductivity (resistivity: 1 kΩ or less), an electromagnetic wave from the coil 8 for inductive coupling plasma is attenuated by the silicon 13, with a result that it becomes difficult to maintain the plasma. Therefore, in place of FIGS. 2(A) and 2(B), as shown in FIGS. 8(A) and 8(B), a single radial beam 14A is formed on a face 7Aa of the dielectric window 7A on the vacuum side, and insulating portions (dielectric side face portions) 40A are formed on the two side faces of the single beam 14A; thus, by blocking off a current generated by a magnetic field in a rotation direction around the center of the dielectric window 7A by the use of the insulating portions (dielectric side face portions) 40A, an electromagnetic wave is propagated in vacuum so that a plasma is generated. A conductive layer 13A is formed in areas other than the peripheral frame portion 7b, that is, on the inner face of the single beam 14A and the inner face of the areas other than the beam 14A (areas indicated by slanting lines in FIG. 8(A)) so that the conductive layer 13A is allowed to suppress oxygen from being discharged from the dielectric window 7 into the vacuum chamber 1A; thus, oxygen is not injected to the sample substrate 9 from the plasma 21 so that the oxygen concentration of the surface of the silicon substrate 9 can be reduced. In accordance with the structure shown in FIG. 8, only the single beam 14A is required to form so that it is possible to simplify the structure and consequently to greatly reduce the manufacturing costs.

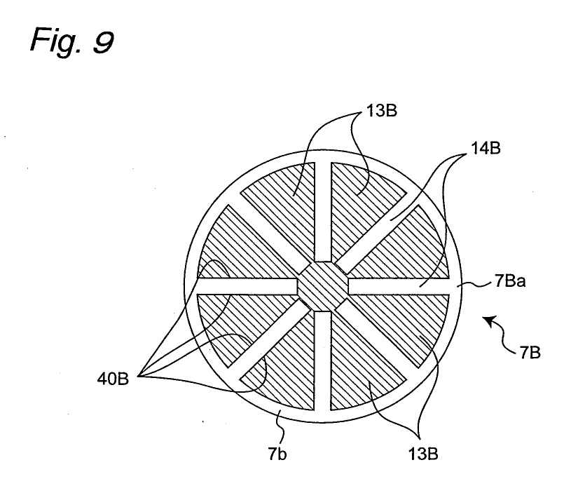

Moreover, in place of FIG. 8, as shown in FIG. 9, another structure may be used in which eight beams 14B are designed so that their end portions on the center side are respectively separated from one another without being coupled to one another, while their end portions on the outer edge side are integrally coupled to the peripheral frame portion 7b of the inner face 7Ba of the window 7B, with all conductive layers 13B (areas indicated by slanting lines in FIG. 9(A)) being coupled to one after another. On the two side faces of each beam 14B, the dielectric member (side face portion) 40B is formed in the same manner as in FIG. 2(B) so that the same functions and effects as those of the aforementioned embodiment can be obtained. In accordance with this structure, since many insulating members are present in a direction perpendicular to the direction of an eddy current, the insulating performance can be further improved.

Additionally, in FIGS. 8 and 9, in the same manner as in the first embodiment, as shown in FIG. 19, the width (dimension in the thickness direction of the window 7) of the insulating portion (insulating layer, that is, dielectric side face portion 40A) for blocking off the electric current (eddy current) 230 in the rotation direction around the center of the dielectric window 7 is preferably set to 10 mm or more. That is, since the height of the beam 14 corresponds to the insulating portion (insulating layer, that is, the dielectric side face portion 40), the height of the beam 14 is desirably set to 10 mm or more. The reason for this is because, when the width of the dielectric side face portion 40 is less than 10 mm, the effect for blocking off an eddy current becomes insufficient.

In this case, the outer end in the radial direction of each of the beams 14A and 14B of the dielectric window 7 through which an electromagnetic wave passes needs to be extended to the outer side farther from the peripheral edge (radius of the outermost circumference) of the coil 8 serving as one example of a generating source of the plasma generation apparatus from the center of each of the windows 7A and 7B. The reason for this is the same as that described in the first embodiment.

The first embodiment and the second embodiment have mainly described about the plasma doping method and apparatus, and the present invention may be applied to a dry etching method and its apparatus.

Moreover, as a modified example of the second embodiment, in place of forming the beam 14A or 14B that protrudes downward from the inner face 7Aa or 7Ba, on the inner face 7Aa or 7Ba of the window 7A or 7B, a concave groove portion corresponding to the beam 14A or 14B may be formed in a manner so as to reverse the concave/convex relationship on its cross section, so that the groove wall faces of the concave groove portion are formed into the dielectric side face portions 40A and 40B.

In a case where a plasma doping process is carried out by using the method and apparatus of the second embodiment as well, the same results as those of the first embodiment can be obtained.

### Other Embodiments

Not limited to the structure in which the beam 14 is formed on the window 7, the present invention may have the following various modes.

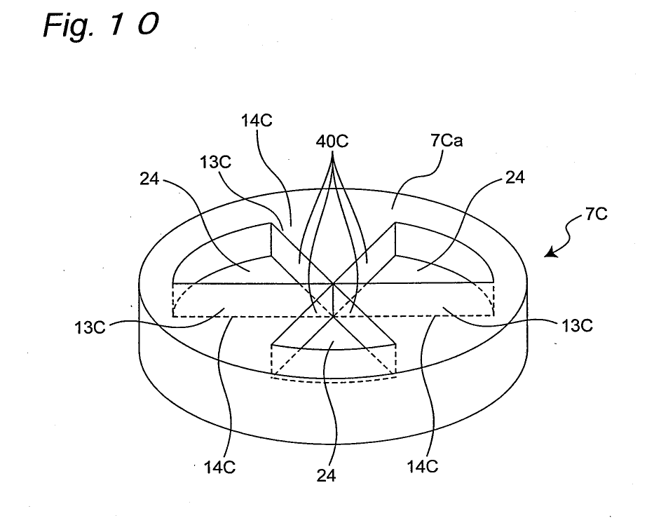

For example, as shown in FIG. 10, in place of the aforementioned rod-shaped beams 14, 14A, and 14B, triangular face members 14C, each having a conductive layer 13C formed on a surface (inner face on the vacuum chamber side) 7Ca, are provided, and a triangular concave portion 24 is formed between the adjacent face members 14C, with side faces along the radial direction of each concave portion 24 being formed as dielectric side face portions 40C, so that a dielectric window 7C is formed.

With this structure, in a case where the dielectric window 7 is made of quartz, it becomes possible to make the manufacturing process simpler, and also to reduce the manufacturing costs, in comparison with the manufacturing process forming the structure with the beam 14.

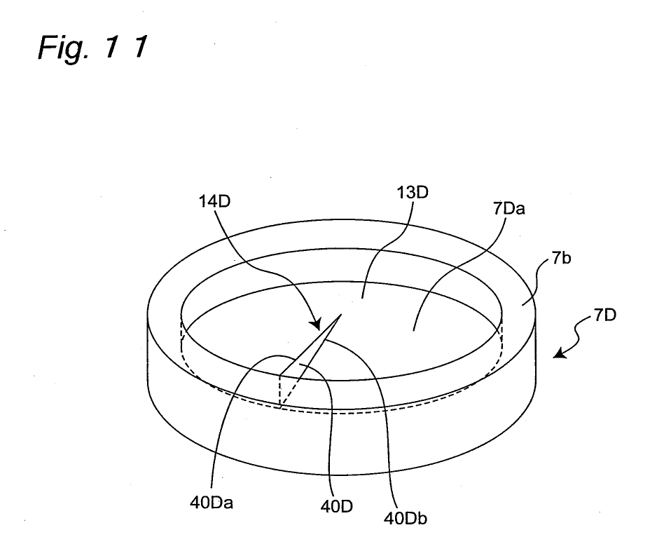

Moreover, as shown in FIG. 11, in place of the aforementioned rod-shaped beams 14, 14A and 14B, a step portion 14D that extends in the radial direction from the center is formed on a surface (inner face on the vacuum chamber side) 7Da, and the side face in the radial direction of the step portion 14D is formed as a dielectric side face portion 40D, and a surface (inner face on the vacuum chamber side) 7Da is formed into such a curved face as to reach an end edge 40Db on the bottom face side of the dielectric side face portion 40D, when rotated in the circumferential direction around the center by 180 degrees from an end edge 40Da on the surface side of the dielectric side face portion 40D, and a conductive layer 13D is formed on the entire face of the surface (inner face on the vacuum chamber side) 7Da or on the entire face of the surface (inner face on the vacuum chamber side) 7Da except for an outer circumferential frame portion 7b so that a dielectric window 7D is formed.

With this structure, in a case where the dielectric window 7 is made of quartz, it becomes possible to make the manufacturing process simpler, and also to reduce the manufacturing costs, in comparison with the manufacturing process forming the structure with the beam 14. Moreover, since this structure sufficiently withstands vacuum, it becomes possible to provide a thinner device.

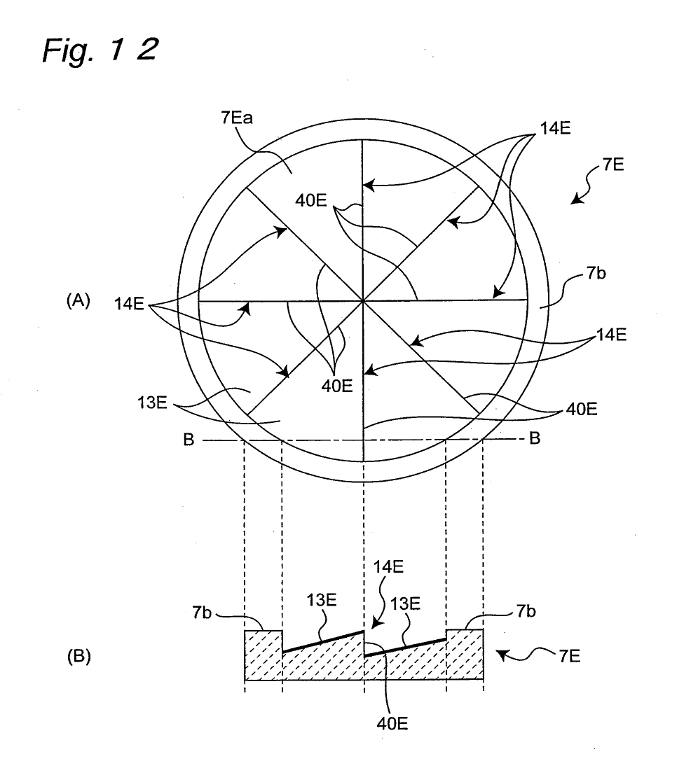

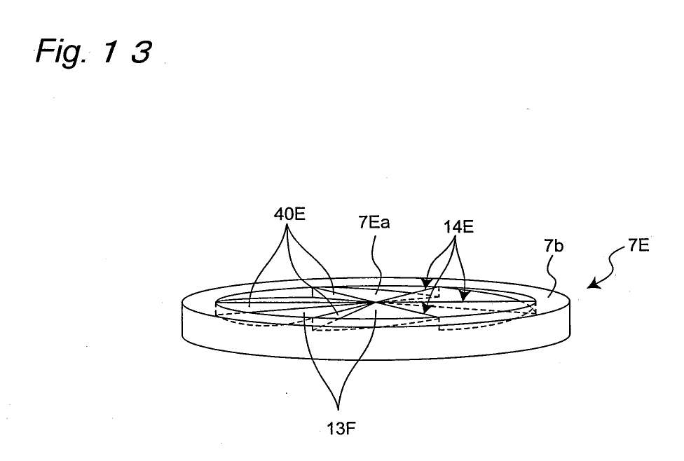

Moreover, as shown in FIGS. 12(A) and 12(B) as well as FIG. 13, in place of the aforementioned single step portion 14D, eight step portions 14E are disposed with equal gaps on a surface (inner face on the vacuum chamber side) 7Ea, with each step portion 14E extending in the radial direction from the center, so that side faces along the radial direction are formed as dielectric side face portions 40E. Furthermore, a slanted plane is formed between the adjacent two dielectric side face portions 40E in a manner so as to allow its end edge on the surface side to reach an end edge on the bottom face side of the other dielectric side face portion 40E of the adjacent two dielectric side face portions 40E, when rotated in the circumferential direction around the center, for example, by 45 degrees from the end edge on the surface side of one of the adjacent two dielectric side face portion 40E, so that a surface 7Ea (inner face on the vacuum chamber side) is formed, and a conductive layer 13E is formed on the entire face of the surface 7Ea (inner face on the vacuum chamber side) or on the entire face of the surface 7Ea (inner face on the vacuum chamber side) except for an outer circumferential frame portion 7b so that a dielectric window 7E is formed.

With this structure, in a case where the dielectric window 7 is made of quartz, it becomes possible to make the manufacturing process simpler, and also to reduce the manufacturing costs, in comparison with the manufacturing process forming the structure with the beam 14. Moreover, since this structure sufficiently withstands vacuum, it becomes possible to provide a thinner device.

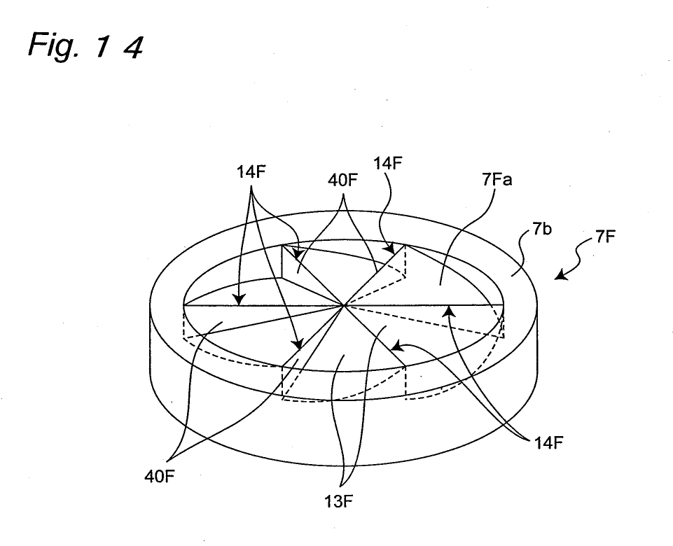

Moreover, as shown in FIG. 14, in place of forming a slanted plane between the adjacent two dielectric side face portions 40E of the aforementioned eight step portions 14E, a slanting curved face may be formed between the adjacent two dielectric side face portions 40F of eight step portions 14F. That is, eight step portions 14F are disposed with equal gaps on a surface (inner face on the vacuum chamber side) 7Fa, with each step portion 14F extending in the radial direction from the center, so that side faces along the radial direction are formed as dielectric side face portions 40F. Furthermore, a slanting curved plane is formed between the adjacent two dielectric side face portions 40F in a manner so as to allow its end edge on the surface side to reach an end edge on the bottom face side of the other dielectric side face portion 40F of the adjacent two dielectric side face portions 40F, when rotated in the circumferential direction around the center, for example, by 45 degrees from the end edge on the surface side of one of the adjacent two dielectric side face portion 40F, so that a surface 7Fa (inner face on the vacuum chamber side) is formed, and a conductive layer 13F is formed on the entire face of the surface 7Fa (inner face on the vacuum chamber side) or on the entire face of the surface 7Fa (inner face on the vacuum chamber side) except for an outer circumferential frame portion 7b so that a dielectric window 7F is formed.

With this structure, in a case where the dielectric window 7 is made of quartz, it becomes possible to make the manufacturing process simpler and also to reduce the manufacturing costs, in comparison with the manufacturing process forming the structure with the beam 14. Moreover, since this structure sufficiently withstands vacuum, it becomes possible to provide a thinner device.

Additionally, the number of steps having the dielectric side face portions is not intended to be limited to one, and a plurality of steps may be formed on the inner face 7a of the window 7 with the same gaps or desired gaps.

In the above-mentioned various embodiments and modified examples of the present invention, with respect to the applicable range of the present invention, only some of many variations relating to the shape of the vacuum container (vacuum chamber) 1, the system and the layout of the plasma generating device, and the like have been exemplified. Needless to say, upon application of the present invention, various variations other than those exemplified here may be proposed.

For example, as the plasma generating device, a plane-shaped coil 8 may be used, or a helicon-wave plasma source, a magnetic neutral loop plasma source, or a magnetic-field-oriented microwave plasma source (electron cyclotron resonance plasma source) may be used. Moreover, as plasma generating means, a discharge can be applied to a parallel flat plate, without interposing an insulating film therebetween, and the surface of the electrode facing the processing substrate 9 thereof may be made of the same material as that for the processing substrate 9. However, even in a case where the above-mentioned plasma source is used, the insulating portion (dielectric side face portion) possessed by the beam 14, or the step portion, or the like on the window 7, which is prepared as an upper quartz plate, needs to be disposed outer side from the peripheral portion of the coil 8 or the antenna from the center. The reason for this is the same as that described earlier.

Moreover, an inert gas other than helium may be used, that is, for example, at least one gas selected from the group consisting of neon, argon, krypton, or xenon (zenon) may be used. These inert gases are advantageous in that they exert less adverse effects on the sample in comparison with the other gases.

Moreover, although the aforementioned embodiments have exemplified a case where the sample 9 is a semiconductor substrate made of silicon, the present invention can be applied upon processing samples made of various other materials.

Furthermore, although the aforementioned embodiments have exemplified a case where arsenic is used as the impurity, the present invention is effectively applied in a case where the sample 9 is a semiconductor substrate made of silicon, that is, in particular, in a case where the impurity is given as arsenic, phosphorous, or antimony, which is applied, in particular, upon manufacturing an n-type semiconductor. The reason for this relates to a characteristic inherent to the element, and is because shallow joined portions can be formed in the transistor portion.

Moreover, the present invention is effectively applied to a case in which the doping concentration is in a low concentration level, and in particular, is effectively used as a plasma doping method and such an apparatus that aim at a range of from 1×10¹¹/cm² to 1×10¹⁷/cm². Furthermore, the present invention is, in particular, effectively used as a plasma doping method and such an apparatus that aim at a range of from 1×10¹¹/cm² to 1×10¹⁴/cm². In a case where the doping concentration is higher than 1×10¹⁷/cm², a conventional ion implantation can be used, while the conventional method fails to deal with devices that require a doping concentration of 1×10¹⁷/cm² or less; however, the present invention can be applied to even this case.

Moreover, the present invention is effective upon reducing the oxygen concentration on the surface of the silicon substrate 9, relative to arsenic, phosphorous, or antimony used upon manufacturing an n-type semiconductor in a plasma doping process; however, upon an occurrence of contamination, the present invention is also effectively used relative to boron, aluminum, or nitrogen used upon manufacturing a p-type semiconductor.

Among the various embodiments, by combining desired embodiments with one another on demand, it becomes possible to provide the respective effects possessed thereby.

A plasma doping apparatus in accordance with the present invention can reduce the film thickness of a layer with a high oxygen concentration on the surface of a processing substrate such as a silicon substrate, to a film thickness as thin as the natural oxidized film, and also to effectively carry out a doping process with a desirable impurity distribution, on a surface of a processing substrate such as a semiconductor circuit device.

Although the present invention has been fully described in connection with the preferred embodiments thereof with reference to the accompanying drawings, it is to be noted that various changes and modifications are apparent to those skilled in the art. Such changes and modifications are to be understood as included within the scope of the present invention as defined by the appended claims unless they depart therefrom.

What is claimed is:

1. A plasma doping apparatus comprising:
a vacuum container forming a vacuum chamber;
an electrode, disposed inside the vacuum chamber, on a substrate mounting face of which a substrate to be processed is mounted;
a supply device for supplying a dopant gas into the vacuum container;
a pressure controlling device for maintaining an inside of the vacuum container at a constant pressure;
a plasma generating device for generating a plasma;
a high-frequency power supply device for applying a high-frequency power to the electrode with the substrate mounted thereon, so that the dopant is injected to a surface of the substrate; and
an insulating window for allowing an electromagnetic wave to passed therethrough, so as to generate the plasma by the plasma generating device, wherein
an insulating side face portion is installed, which extends radially from a center of a generating unit of the plasma generating device, and is disposed on a surface of the window on the vacuum chamber side so as to be orthogonal to the substrate mounting face of the electrode, and
a conductive layer made of a material identical to that for the substrate is provided in an area corresponding to the generating unit of the plasma generating device on the surface of the window on the vacuum chamber side.

2. The plasma doping apparatus according to claim 1, wherein the insulating side face portion of the window is constituted by side faces along radial directions of beams that radially extend from a center portion of the window, each of the beams having a height of 10 mm or more, with the side faces of the beams each being made of an insulating substance.

3. The plasma doping apparatus according to claim 1, wherein the dopant gas, which contains arsenic or phosphorous atoms, is an element selected from the group consisting of arsine, phosphine, arsenic trifluoride, arsenic pentafluoride, arsenic trichloride, arsenic pentachloride, phosphorous trichloride, phosphorous pentachloride, phosphorous trifluoride, phosphorous pentafluoride, and phosphorous oxychloride.

4. The plasma doping apparatus according to claim 1, wherein the insulating side face portion of the window is constituted by a side face along a radial direction of a single beam that radially extends from a center portion of the window.

5. The plasma doping apparatus according to claim 1, wherein the window is made of an insulating substance having a resistivity of 10 kΩcm or more.

6. The plasma doping apparatus according to claim 1, wherein the conductive layer of the window has a resistivity of 1 kΩcm or less.

7. The plasma doping apparatus according to claim 1, wherein the insulating side face portion of the window is constituted by side faces along radial directions of beams that radially extend from a center portion of the window, each of the beams being disposed in an area inside a peripheral frame portion of the window to be tightly made in contact with and secured to the vacuum container.

8. The plasma doping apparatus according to claim 1, wherein an induction coupling plasma source, a helicon-wave plasma source, a magnetic neutral loop plasma source, or a magnetic-field-oriented microwave plasma source is used as a means for generating the plasma.

9. The plasma doping apparatus according to claim 8, wherein the insulating side face portion of the window is constituted by side faces along radial directions of beams that radially extend from a center portion of the window, with outer edges of the beams in the radial directions of the window for allowing an electromagnetic wave to be transmitted therethrough being positioned outside an outer edge of the generating unit of the plasma generating device while extending from a center of the window.

10. The plasma doping apparatus according to claim 1, wherein the insulating side face portion of the window is constituted by a side face along a radial direction of a concave portion that is placed on the surface of the window on the vacuum chamber side.

11. The plasma doping apparatus according to claim 1, wherein the insulating side face portion of the window is constituted by a side face along a radial direction of a step portion that radially extends from a center portion of the window.
